(19) United States
(12) Patent Application Publication
(10) Pub. No.: US 2010/0070838 A1
(43) Pub. Date: Mar. 18, 2010

(54) SYSTEM AND METHOD FOR DETECTING AND IGNORING AN INVALID CHANNEL MAP FEATURE

(75) Inventors: Steven L. Cooper, Whitestown, IN (US); Bert D. Hawkins, Brownsburg, IN (US)

Correspondence Address: FLETCHER YODER P.C., 7915 FM 1960 RD. WEST, SUITE 330, HOUSTON, TX, 77070, US

(73) Assignee: Shenzhen TCL New Technology Ltd., Shenzhen (CN)

(21) Appl. No.: 12/447,873

(22) PCT Filed: Nov. 8, 2006
(86) PCT No.: PCT/US06/43789

§ 371 Date: Apr. 29, 2009

(51) Int. Cl. H03M 13/00; G06F 11/10

(52) U.S. Cl. 714/807; 714/E11.001

(57) ABSTRACT

There is provided a system and method for detecting an ignoring an invalid channel map feature. More specifically, in one embodiment, there is provided a method, comprising receiving an initial channel map feature, determining a cyclic redundancy check value for the initial channel map feature, receiving a subsequent channel map feature, determining a cyclic redundancy check value for the subsequent channel map feature, and processing the initial or the subsequent channel map feature if the cyclic redundancy check values for each of the initial and subsequent cyclic redundancy check values match.

### CROSS-REFERENCE TO RELATED APPLICATIONS

This application is a National Phase 371 Application of PCT Application No. PCT/US06/43789, filed Nov. 8, 2006, entitled “SYSTEM AND METHOD FOR DETECTING AND IGNORING AN INVALID CHANNEL MAP FEATURE”.

### FIELD OF THE INVENTION

The present invention relates generally to a system and method for avoiding inefficiencies associated with invalid channel map features for digital-cable-ready (DCR) systems.

### BACKGROUND OF THE INVENTION

This section is intended to introduce the reader to various aspects of art, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

Digital cable, a service offered by many cable distributors, utilizes digital technology to facilitate provision of a larger number of channels to users than would be available with analog channels alone. Using video compression and digital channels, cable distributors may increase the number and diversity of programs available on their existing cable networks without requiring network additions.

In a DCR system, it may be desirable or necessary to store a channel map to facilitate navigation through available broadcasts. A channel map may be defined as a list of channels present in a given cable or antenna lineup. Channel maps for cable systems are generally transmitted by a cable provider to a user's television from a cable head end via a map source, such as a Personal Computer Memory Card International Association (PCMCIA) CableCard. It has now been recognized that invalid channel map features may be sent from certain manufacturer's CableCards to a television. Such transmissions generally occur after certain recognized events (e.g., a reset). These invalid channel map features can cause temporary, but lengthy, channel map instabilities (e.g., missing channels) that may annoy a user. Accordingly, a system and method that effectively reduces these instabilities by avoiding inefficiencies associated with the invalid channel map features is desirable.

### SUMMARY OF THE INVENTION

Certain aspects commensurate in scope with the disclosed embodiments are set forth below. It should be understood that these aspects are presented merely to provide the reader with a brief summary of certain forms the invention might take and that these aspects are not intended to limit the scope of the invention. Indeed, the invention may encompass a variety of aspects that may not be set forth below.

In accordance with present embodiments, there is provided a system and method for detecting and ignoring an invalid channel map feature. More specifically, in one embodiment, there is provided a method, comprising receiving an initial channel map feature, determining a cyclic redundancy check value for the initial channel map feature, receiving a subsequent channel map feature, determining a cyclic redundancy check value for the subsequent channel map feature, and processing the initial or the subsequent channel map feature if the cyclic redundancy check values for each of the initial and subsequent cyclic redundancy check values match.

### BRIEF DESCRIPTION OF THE DRAWINGS

Advantages of the invention may become apparent upon reading the following detailed description and upon reference to the drawings in which:

FIG. 1 is a block diagram of an electronic device in accordance with an exemplary embodiment of the present invention;

FIG. 2 is a process flow diagram representing cable channel map processing in accordance with an exemplary embodiment of the present invention;

FIG. 3 is a process flow diagram representing a procedure for accommodating submission of invalid channel map features in accordance with an exemplary embodiment of the present invention;

FIG. 4 is a process flow diagram representing a procedure for accommodating submission of invalid channel map features in accordance with an exemplary embodiment of the present invention; and

FIG. 5 is a process flow diagram representing a procedure for accommodating submission of invalid channel map features in accordance with an exemplary embodiment of the present invention.

### DETAILED DESCRIPTION

One or more specific embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

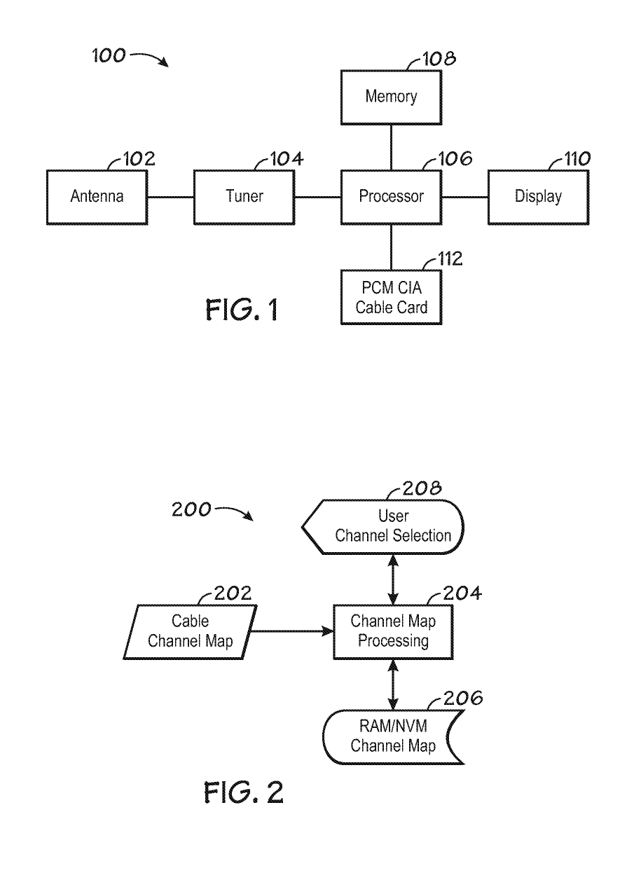

FIG. 1 is a block diagram of an electronic device in accordance with an exemplary embodiment of the present invention. The electronic device (e.g., a television) is generally referred to by the reference number 100. The electronic device 100 comprises a receptor (e.g., a cable inlet or an antenna), a tuner 104, a processor 106, a memory 108, and a display 110. The memory 108 may be adapted to hold machine-readable computer code that causes the processor 106 to perform an exemplary method in accordance with the present invention. The processor 106 may receive cable channel map data and/or other information from a service provider (e.g., a cable provider) via a map source 112 that is external or internal to the electronic device 100. The map source 112 may include a cable box, a PCMCIA CableCard, or the like.

FIG. 2 is a process flow diagram 200 representing cable channel map processing in accordance with an exemplary embodiment of the present invention. Specifically, FIG. 2 illustrates a cable channel map 202 that may be provided through the map source 112 of FIG. 1. The channel map 202 may originate from a service provider (e.g., a cable provider) or a device (e.g., the map source 112). The channel map 202 may be processed in block 204 by a channel map processing unit and added to a channel map database 206 stored in random access memory (RAM), non-volatile memory (NVM) or the like. For example, mapping channels (e.g., video signals) and storing them in memory may include searching available channels and mapping those with a sufficiently clear signal. Further, block 208 represents selection of channels for display by a user. For example, this may include selecting certain channel numbers on a television panel or remote control for display of the associated content on a television screen.

In a DCR system (e.g., electronic device 100), it is generally desirable or necessary to store a channel map as transmitted by a cable provider to enable channel navigation. A cable provider's programming and so forth may change over time. Accordingly, the channel map may be updated or rebuilt periodically to include such changes. Channel maps are generally built up from various channel map tables, as provided in the American National Standards Institute/Society of Cable Telecommunications Engineers 65 standard (ANSI/SCTE 65). The ANSCl/SCTE 65 standard also provides for the specification of virtual channel numbers. One of the primary tables utilized to build up the channel maps is the Defined Channel Map (DCM), which specifies which virtual channels are “On” versus “Off.” These designations (i.e., “On” and “Off”) for channels in the DCM operate to include or exclude certain channels from the channel map. For example, if another table (e.g., the Virtual Channel Map (VCM)) provides information about a channel and the DCM has specified that it is “Off,” then that channel is not allowed to be presented (e.g., displayed) to the user. Thus, the DCM has significant control over the channel map.

Periodically, new DCMs may be provided to the DCR system. The new DCMs may be the result of changes in programming, a device reset, or the like. When a new DCM arrives, the channel map is typically rebuilt based on the newly acquired information included in the new DCM and/or other related tables. During this rebuilding process, the television utilizing the channel map may have inconsistent performance. For example, rebuilding of a channel map associated with a new DCM can cause temporary channel map instabilities which may manifest as missing channels or other odd behavior.

It is now recognized that some of the instabilities discussed above can be avoided by addressing occasional submissions of invalid DCMs by channel map sources (e.g., CableCards) produced by certain manufacturers. An invalid DCM is typically sent as the first table from a map source. The invalid DCM may contain a complete, ascending list of thousands of virtual channels beginning with the first virtual channel, wherein all of the channels are defined as “Off.” Shortly after this invalid data is transmitted, the map source may begin sending actual channel map information that is sent from a head end. That is to say, the map source itself or a related device may initially transmit an invalid DCM that is eventually replaced by an actual DCM originating from a service provider. The initial transmission of the invalid DCM may cause substantial instability. For example, an invalid DCM could cause all of the channels to be inaccessible until the actual DCM is transmitted.

Accordingly, embodiments of the present invention detect and/or ignore invalid DCMs.

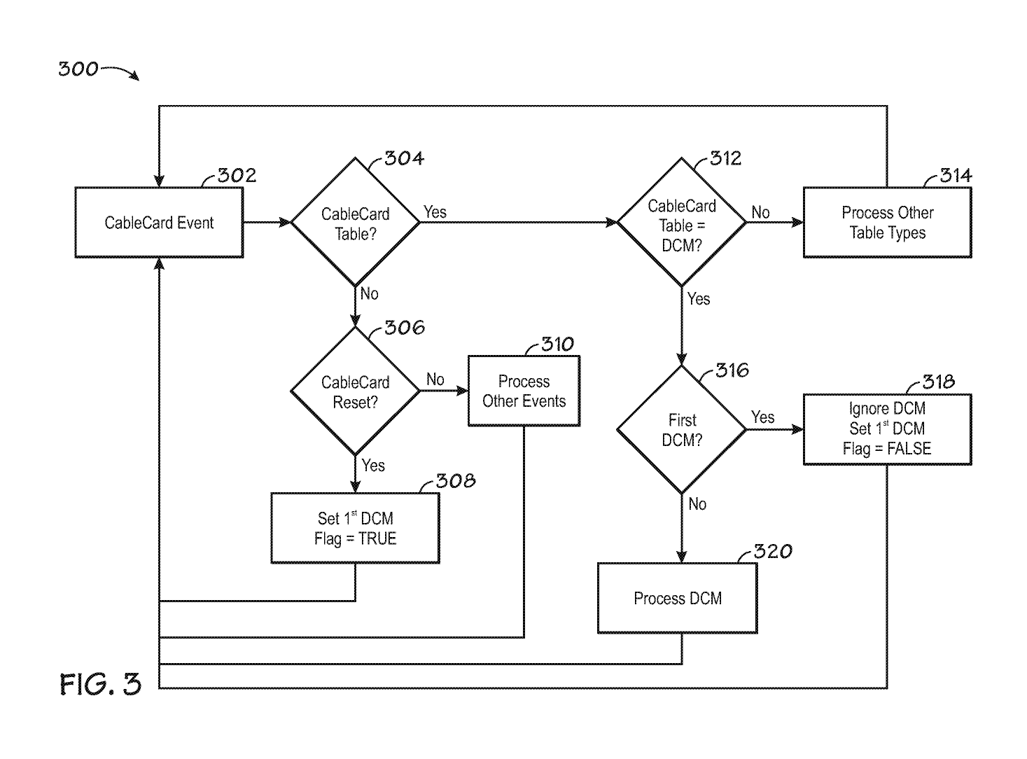

FIG. 3 is a process flow diagram representing a procedure for accommodating submission of invalid channel map features in accordance with an exemplary embodiment of the present invention. The exemplary procedure in FIG. 3 is generally designated by reference numeral 300. According to procedure 300, in the event that a map source (e.g., CableCard) is reset or otherwise initiates an initial channel map submission, the first DCM provided is ignored. As discussed above, the first DCM provided by certain manufacturer's map sources (e.g., CableCards) after a map source reset can be invalid. Accordingly, the procedure 300 may prevent electronic devices from accepting invalid DCMs and, thus, prevent the associated instabilities.

Specifically, the procedure 300 is initiated when a certain event occurs or is recognized. Block 302 represents a CableCard event. For example, the CableCard event may include a CableCard reset. The CableCard event may also include a new channel map component submission after a CableCard reset or the like (e.g., a CableCard error or insertion of an external CableCard). If a new channel map is provided, it may be provided in the form of multiple different tables that are eventually combined to build the entire channel map.

Once the CableCard event occurs in block 302, various determinations are made regarding the event and actions are taken based on these determinations. In block 304, it is determined whether a CableCard table has been submitted. If a CableCard table has not been submitted, a determination is made in block 306 as to whether a CableCard reset occurred. If a CableCard reset occurred, a first DCM flag is set to a TRUE value in block 308 to facilitate detection of a first DCM and the procedure 300 continues by starting over at block 302. If a CableReset did not occur, other events are processed in block 310. Returning now to block 304, if it is determined that a CableCard table has been submitted, it is determined in block 312 whether the CableCard table is a DCM or another table type (e.g., VCM). If the CableCard table is not a DCM, it is processed in block 314. If the CableCard table is a DCM, it is determined in block 316 whether the DCM is a first DCM (e.g., whether the first DCM flag is set to TRUE or FALSE). If it is the first DCM, it is potentially invalid. Accordingly, the first DCM is ignored and the first DCM flag is set to a FALSE value in block 318. If the first DCM has already been received, and the first DCM flag has been set to the FALSE value, block 316 will direct the procedure to block 320 and the DCM will be processed.

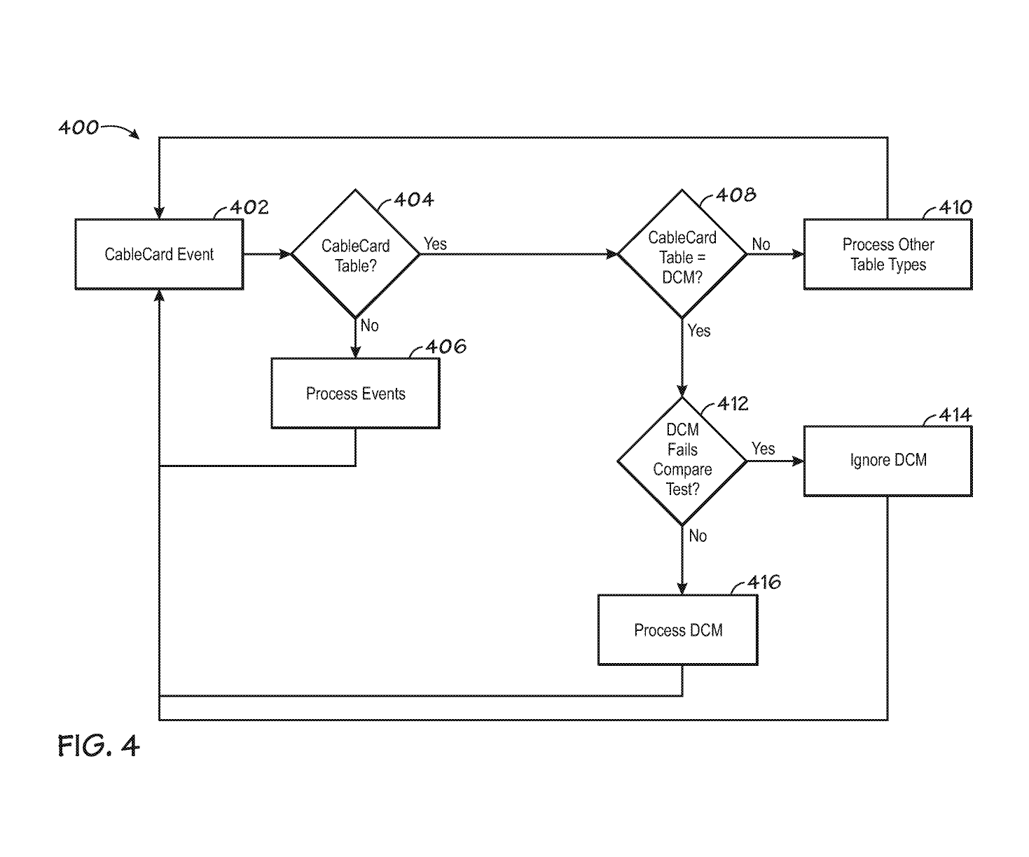

FIG. 4 is a process flow diagram representing a procedure for accommodating submission of invalid channel map features in accordance with an exemplary embodiment of the present invention. The procedure in FIG. 4 is generally designated by reference numeral 400. According to procedure 400, a submitted DCM is compared to an existing channel map to determine whether it is invalid. For example, in one exemplary embodiment, if the newly submitted DCM defines all of the channels as “Off,” it may be deemed invalid because the generally static nature of cable channel maps dictates that all channels will not likely be removed by a valid DCM. In another embodiment, if it is determined that all of the channels in a limited range of channels are defined as “Off,” the newly submitted DCM may be deemed invalid. Indeed, a heuristic covering an unexpected range or threshold of channels may be defined to facilitate such a determination. For example, if it is determined that all channels in block 1000-2000 are defined as “Off,” wherein 100 of the channels in the block are good channels, the DCM may be deemed invalid. Accordingly, the procedure 400 may prevent electronic devices from accepting invalid DCMs and, thus, prevent the associated instabilities.

Specifically, the procedure 400 is initiated when a certain event occurs or is recognized. Block 402 represents a CableCard event. For example, the CableCard event may include a CableCard reset. The CableCard event may also include a new channel map component submission after a CableCard reset or the like (e.g., a CableCard error or insertion of an external CableCard). If a new channel map is provided, it may be provided in the form of multiple different tables that are eventually combined to build the entire channel map.

Once the CableCard event occurs in block 402, various determinations are made regarding the event and actions are taken based on these determinations. In block 404, it is determined whether a CableCard table has been submitted. If a CableCard table has not been submitted, other events are processed in block 406. If it is determined that a CableCard table has been submitted, it is determined in block 408 whether the CableCard table is a DCM or another table type (e.g., VCM). If the CableCard table is not a DCM, it is processed in block 410. Otherwise, if the CableCard table is a DCM, it is determined in block 412 whether the DCM fails a comparison test (e.g., whether all channels are defined as “Off”). If the DCM fails the comparison test in block 412, it is deemed invalid and ignored in block 414. If the DCM passes the comparison test, it is likely a valid DCM and block 412 will direct the procedure process the DCM in block 416.

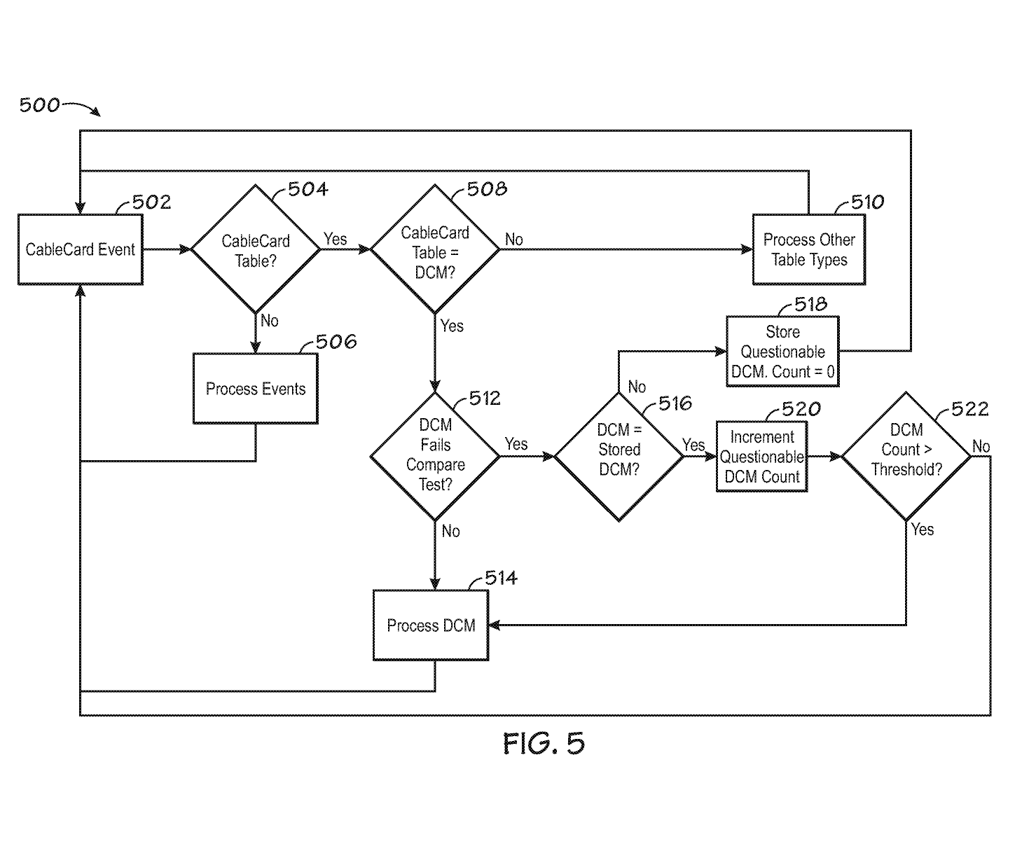

FIG. 5 is a process flow diagram representing a procedure for accommodating submission of invalid channel map features in accordance with an exemplary embodiment of the present invention. The procedure in FIG. 5 is generally designated by reference numeral 500. According to procedure 500, a DCM or channel map may be stored (e.g., stored in a television memory component) and compared with incoming DCMs or channel maps to determine whether or not the data should be ignored. In some embodiments, rather than store the entire DCM or channel map, a unique identifier (e.g., a cyclical redundancy check (CRC)) for the DCM or channel map may be stored for comparison. For example, a CRC for an initial DCM deemed invalid may be stored and utilized for comparison with CRCs for incoming DCMs to determine whether the designation of the initial DCM as invalid was proper.

Features of the procedure 500 may be combined with one or more of the procedures set forth above to prevent discarding valid DCMs. Indeed, according to the procedure 500, a CRC for a DCM may be utilized in a similar fashion to a checksum to determine whether an initial DCM is equivalent to each of multiple incoming DCMs and, thus, whether the initial DCM is likely valid or invalid. For example, in one embodiment, after ignoring an initial DCM (e.g., the first DCM received or a DCM deemed invalid), a stored CRC for the ignored DCM may be compared with the CRCs of incoming DCMs. If it is determined based on a comparison of the CRCs for the incoming DCMs that the same potentially invalid DCM is being sent repeatedly (e.g., a designated number of times within a limited time frame), it may be considered valid. This determination of validity may be supported because it is unlikely that an invalid DCM would be sent multiple times in a limited period. Confidence in the validity of the DCM may increase as more equivalent DCMs are submitted.

Specifically, the procedure 500 is initiated when a certain event occurs or is recognized. Block 502 represents a CableCard event. For example, the CableCard event may include a CableCard reset. The CableCard event may also include a new channel map component submission after a CableCard reset or the like (e.g., a CableCard error or insertion of an external CableCard). If a new channel map is provided, it may be provided in the form of multiple different tables that are eventually combined to build the entire channel map. Block 502 may also include determining the CRC for a received channel map feature (e.g., the CRC for a DCM).

Once the CableCard event occurs in block 502, various determinations are made regarding the event and actions are taken based on these determinations. In block 504, it is determined whether a CableCard table has been submitted. If a CableCard table has not been submitted, other events are processed in block 506. If it is determined that a CableCard table has been submitted, it is determined in block 508 whether the CableCard table is a DCM or another table type (e.g., VCM). If the CableCard table is not a DCM, it is processed in block 510. Otherwise, if the CableCard table is a DCM, it is determined in block 512 whether the DCM fails a comparison test (e.g., whether all channels are defined as “Off”). If the DCM does not fail the comparison test in block 512, it is deemed valid and processed in block 514. If the DCM fails the comparison test, the DCM is compared to one or more stored DCMs in block 516. In some embodiments, the comparison in block 516 may include comparing two or more CRCs of channel maps or channel map features (e.g., DCMs).

In block 518, a determination is made as to whether the DCM or a related CRC has been stored previously. If the DCM has not been stored it is stored and a related DCM count variable is set to zero. If the DCM has been stored, the related DCM count variable is incremented (e.g., changed from 0 to 1) in block 520. In block 522, a determination is made as to whether the DCM count variable is greater than a threshold (e.g., a user defined limit that is indicative of validity). If the DCM count variable is less than or equal to the threshold in block 522, the DCM may be invalid and the process returns to block 502. If the DCM count variable is higher than the threshold, it is likely that the DCM is valid and it is processed in block 514. This may result in preventing embodiments of the present invention from discarding valid DCMs. It should be noted that in some embodiments, block 522 may determine whether the DCM count variable is equivalent to the threshold.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method, comprising:
receiving an initial channel map feature;
determining a cyclic redundancy check value for the initial channel map feature;
receiving a subsequent channel map feature;
determining a cyclic redundancy check value for the subsequent channel map feature; and
processing the initial or the subsequent channel map feature if the cyclic redundancy check values for each of the initial and subsequent cyclic redundancy check values match.

2. The method of claim 1, comprising incrementing a count variable each time the cyclic redundancy check value for the initial channel map feature matches a cyclic redundancy check value for a later received channel map feature.

3. The method of claim 2, comprising:
comparing the count variable to a threshold; and
processing the initial or the subsequent channel map feature if the cyclic redundancy check values for each of the initial and subsequent cyclic redundancy check values match, and the count variable is greater than the threshold.

4. The method of claim 2, comprising:
comparing the count variable to a threshold; and
processing the initial or the subsequent channel map feature if the cyclic redundancy check values for each of the initial and subsequent cyclic redundancy check values match, and the count variable is equal to the threshold.

5. The method of claim 1, wherein the channel map feature comprises a defined channel map.

6. The method of claim 1, comprising storing the cyclic redundancy check value for the initial channel map feature in a television memory component.

7. The method of claim 1, comprising determining whether the initial channel map feature is a defined channel map.

8. A method, comprising:
determining a nature of a map source event;
determining a type of a channel map table, if the map source event is found to be the channel map table;
determining whether a defined channel map is a first defined channel map to be received after a reset, if the channel map table is found to be the defined channel map; and
ignoring the defined channel map if it is the first to be received after the reset.

9. The method of claim 8, comprising processing the channel map table if it is found not to be the defined channel map.

10. The method of claim 8, wherein the map source event is the reset.

11. The method of claim 8, comprising setting a defined channel map flag to a value of true when the map source event is the reset to facilitate determining whether the first defined channel map has been received.

12. The method of claim 8, comprising setting a defined channel map flag to a value of false after ignoring the first defined channel map to be received.

13. The method of claim 8, comprising processing the map source event if it is not the reset or the channel map table.

14. A system, comprising:
a first determination module configured to determine a nature of a map source event;
a second determination module configured to determine a type of channel map table of the map source event, if the map source event is found to be a channel map table;
a third determination module configured to determine whether the channel map table fails a comparison test with stored data, if the channel map table is found to be a defined channel map; and
a bypass module configured to bypass processing the defined channel map, if the defined channel map fails the comparison test.

15. The system of claim 14, wherein the map source event is a CableCard event.

16. The system of claim 14, wherein the third determination module is configured to compare a cyclic redundancy check for the channel map table with a previously stored cyclic redundancy check.

17. The system of claim 14, comprising a memory configured to store the map source event.

18. The system of claim 14, comprising a cable ready television.

19. The system of claim 14, comprising a cable box that is configured to generate the map source event.

20. The system of claim 14, wherein the stored data includes information from a previously received map source event.
